(19) United States
(12) Patent Application Publication
(10) Pub. No.: US 2014/0356789 A1
(43) Pub. Date: Dec. 4, 2014

(54) FLUORINATED PHOTOPOLYMER WITH INTEGRATED ANTHRACENE SENSITIZER

(71) Applicant: Orthogonal, Inc., Rochester, NY (US)

(72) Inventors: Charles Warren Wright, Fairport, NY (US); Ralph Rainer Dammel, Chonburi (TH)

(21) Appl. No.: 14/291,767

(22) Filed: May 30, 2014

Related U.S. Application Data
(60) Provisional application No. 61/829,556, filed on May 31, 2013.

(51) Int. Cl. G03F 7/038; G03F 7/42; G03F 7/20

(52) U.S. Cl. CPC G03F 7/0388; G03F 7/20; G03F 7/42
USPC 430/285.1; 430/325; 430/323; 430/287.1

(57) ABSTRACT

A method of patterning a device comprises providing on a device substrate a layer of a fluorinated photopolymer comprising at least three distinct repeating units including a first repeating unit having a fluorine-containing group, a second repeating unit having an acid- or alcohol-forming precursor group, and a third repeating unit having an anthracene-based sensitizing dye. The photopolymer has a total fluorine content in a range of 15 to 60% by weight. The photopolymer layer is exposed to patterned light and contacted with a developing agent to remove a portion of exposed photopolymer layer in accordance with the patterned light, thereby forming a developed structure having a first pattern of photopolymer covering the substrate and a complementary second pattern of uncovered substrate corresponding to the removed portion of photopolymer. The developing agent comprises at least 50% by volume of a fluorinated solvent.

### CROSS REFERENCE TO RELATED APPLICATIONS

This application claims the benefit of U.S. Provisional Application No. 61/829,556 filed May 31, 2013, the entire disclosure of which is hereby incorporated herein by reference.

### STATEMENT REGARDING FEDERALLY-SPONSORED RESEARCH OR DEVELOPMENT

This invention was made in part with Government support under SBIR Phase II Grant No. 1230454 awarded by the National Science Foundation (NSF). The government may have certain rights in the invention.

### BACKGROUND

1. Field of the Invention

The present invention relates to fluorinated photopolymers having one or more photosensitizers incorporated into the polymer. Such photopolymers are particularly useful for patterning organic electronic and biological materials.

2. Discussion of Related Art

Organic electronic devices offer significant performance and price advantages relative to conventional inorganic-based devices. As such, there has been much commercial interest in the use of organic materials in electronic device fabrication. Specifically, organic materials such as conductive polymers can be used to manufacture devices that have reduced weight and drastically greater mechanical flexibility compared to conventional electronic devices based on metals and silicon. Further, devices based on organic materials are likely to be significantly less damaging to the environment than devices made with inorganic materials, since organic materials do not require toxic metals and can ideally be fabricated using relatively benign solvents and methods of manufacture. Thus, in light of these superior weight and mechanical properties, and particularly in light of the lowered environmental impact in fabrication and additionally in disposal, electronic devices based on organic materials are expected to be less expensive than devices based on conventional inorganic materials.

Fabrication of electronic devices, whether from organic or inorganic materials, requires the creation on an industrial scale of precisely defined patterns of the organic or inorganic active materials in these devices, often at a microscopic level. Most commonly, this is accomplished by “photolithography,” in which a light-sensitive “photoresist” film that has been deposited on a substrate is exposed to patterned light. Although this can be done in numerous ways, typically a microscopic pattern of light and shadow created by shining a light through a photographic mask is used to expose the photoresist film, thereby changing the chemical properties of the portions of the photoresist that have been exposed to light. In a “positive” photoresist, the portions of the photoresist that are exposed to light become soluble in the “developer” solution that is then applied to the exposed photoresist, and the light-exposed portions of the photoresist are washed away (“developed”) by the developer solvent to leave a pattern of unexposed photoresist and newly exposed underlying substrate. A “negative” photoresist is treated as for a positive photoresist; however, in a negative photoresist, it is the unexposed rather than the exposed portions of the photoresist that are washed away by the developing.

In a standard process, the photoresist material is laying on top of an active material layer that is to be patterned. Once the development has taken place, the underlying layer is etched using either a liquid etchant or a reactive ion etch plasma (RIE) with the appropriate etch chemistry. In either case, the photoresist layer blocks the etching of active material directly beneath it. Once the etching is complete, the resist is stripped away, leaving the pattern of active material on the substrate.

Alternatively, the photoresist can be used with a so-called “liftoff” technique. In this case, the resist is processed on a substrate before the active material layer is deposited. After the photoresist pattern is formed, the active material is deposited on both the substrate and the photoresist. In an additional “lift-off” or “stripping” step, remaining photoresist along with an overlying layer of active material is removed via the appropriate solvent to leave the desired patterned active material.

Although the use of photoresists is routine in traditional electronic devices based on inorganic materials, photolithography has been difficult to obtain for devices using organic materials, thereby hindering the development of devices based on these materials. Specifically, organic materials are much less resistant to the solvents that are used for conventional photolithography, as well as to the intense light sources that are used in these processes, with the result that conventional lithographic solvents and processes tend to degrade organic electronics. Although there have been various attempts to overcome these problems, e.g., by ink jet printing or shadow mask deposition, these alternative methods do not produce the same results as would be obtained with successful photolithography. Specifically, neither ink jet printing nor shadow mask deposition can achieve the fine pattern resolutions that can be obtained by conventional lithography, with ink-jet printing limited to resolutions of approximately 10-20 μm and shadow mask deposition to resolutions of about 25-30 μm.

US 2011/0159252 discloses a useful method for patterning organic electronic materials by an “orthogonal” process that uses fluorinated solvents and fluorinated photoresists. The fluorinated solvents have very low interaction with organic electronic materials.

Although the orthogonal process has made good progress, these fluorinated systems not always have sufficient sensitivity to the exposing radiation, especially in the range of 330 to 450 nm. Many conventional photoresist compositions include a photosensitizing additive, commonly referred to as a sensitizer or sensitizing dye, to increase the photosensitivity of the photoresist at a particular wavelength. By varying the amount of sensitizer added to the photoresist, the photo speed and spectral sensitivity of the system can be modulated. An important technical limitation of most existing sensitizers is that they are not highly soluble in fluorinated coating solvents or fluorinated developing solutions. Consequently, the concentration of sensitizer that can be employed in fluorinated photoresist composition is very limited and development can leave behind a residue of the sensitizer. Secondly, some sensitizers are susceptible to sublimation during the baking process, thereby depleting the photoresist formulation of sensitizer. In addition, the sublimed sensitizer can coat the baking tools and then flake off during the subsequent processing, resulting in further problems in the system.

In light of the above, there is a need to provide a more effective sensitization for use with fluorinated photoresists/fluorinated solvent systems.

### SUMMARY

In accordance with the present disclosure, a method comprises: providing on a device substrate a layer of a fluorinated photopolymer comprising at least three distinct repeating units including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight; exposing the photopolymer layer to patterned light to form an exposed photopolymer layer; and contacting the exposed photopolymer layer with a developing agent to remove a portion of the exposed photopolymer layer in accordance with the patterned light, thereby forming a developed structure having a first pattern of photopolymer covering the substrate and a complementary second pattern of uncovered substrate corresponding to the removed portion of photopolymer, the developing agent comprising at least 50% by volume of a fluorinated solvent.

In accordance with another aspect of the present disclosure, a composition comprises: a fluorinated solvent; and a fluorinated photopolymer comprising at least three distinct repeating units, including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight.

In an embodiment, the compositions of the present disclosure have improved light sensitivity relative similar compositions without the third repeating unit, thereby requiring less exposure energy. When used to pattern other light-sensitive materials, the reduced light exposure may reduce possible degradation. In an embodiment, the improved light sensitivity may further enable reducing the amount of optional photo-acid generator. In an embodiment, incorporation of the anthracene sensitizing dye directly into the copolymer may overcome solubility problems of related, small molecule anthracene compounds that are otherwise difficult to incorporate into the system in effective amounts.

### BRIEF DESCRIPTION OF DRAWINGS

FIG. 1 is a flow chart depicting the steps in an embodiment of the present invention;

FIG. 2A-2F is a series of cross-sectional views depicting various stages in the formation of a patterned active organic material structure according to an embodiment of the present invention; and

FIG. 3A-3D is a series of cross-sectional views depicting various stages in the formation of a patterned active organic material structure according to another embodiment of the present invention.

### DETAILED DESCRIPTION

It is to be understood that the attached drawings are for purposes of illustrating the concepts of the invention and may not be to scale.

A photopolymer includes a light-sensitive material that can be coated to produce a photo-patternable film. In an embodiment, photopolymers of the present disclosure may be used to pattern a layer of some useful material in a device, e.g., a multilayer electronic device, and the photopolymer may optionally be removed (stripped). In an embodiment, photopolymers of the present disclosure may remain as part of a device and be used to form, e.g., a pattered a dielectric film or a water and/or oil repellent structure. The photopolymers described herein are sometimes referred to as “photoresists”, but the photopolymers can have uses other than in photolithography, as would be readily apparent to one skilled in the art. That is, the term “photoresist” as used to describe materials of the present disclosure is not limited to photosensitive polymers used only in photolithography. An embodiment of the present disclosure is directed to improved polymeric, fluorinated photoresists (fluorinated photopolymers) that incorporate an anthracene sensitizing dye moiety as part of the polymer. The photopolymer is particularly suited for coating and developing using fluorinated solvents. The solvents for the fluorinated photopolymer solution, the developing solution and optional stripping solution are each chosen to have low interaction with other material layers that are not intended to be dissolved or otherwise damaged. Such solvents and solutions are collectively termed “orthogonal”. This can be tested by, for example, immersion of a device comprising the material layer of interest into the solvent or solution prior to operation. The solvent or solution is orthogonal if there is no serious reduction in the functioning of the device. Unless otherwise noted, the term “solution” is used broadly herein to mean any flowable material. Examples of “solutions” include, but are not limited to: single solvent liquids; homogeneous mixtures of a solvent with one or more other solvents, with one or more solutes, and combinations thereof; and heterogeneous or multi-phase mixtures such as emulsions, dispersions and the like.

Certain embodiments disclosed in the present disclosure are particularly suited to the patterning of solvent-sensitive, active organic materials. Examples of active organic materials include, but are not limited to, organic electronic materials, such as organic semiconductors, organic conductors, OLED (organic light-emitting diode) materials and organic photovoltaic materials, organic optical materials, medical materials and biological materials (including bioelectronic materials). Many of these materials are easily damaged when contacted with organic or aqueous solutions used in conventional photolithographic processes. Active organic materials are often coated to form a layer that may be patterned. For some active organic materials, such coating can be done from a solution using conventional methods. Alternatively, some active organic materials are coated by vapor deposition, for example, by sublimation from a heated organic material source at reduced pressure. Solvent-sensitive, active organic materials can also include composites of organics and inorganics. For example, the composite may include inorganic semiconductor nanoparticles (quantum dots). Such nanoparticles may have organic ligands or be dispersed in an organic matrix.

The photoresist compositions of the present disclosure are provided in a coating solution including at least 50% by volume of a fluorinated solvent, preferably at least 90% by volume. An exposed photoresist layer can be developed using a developing solution including at least 50% by volume of a fluorinated solvent, preferably at least 90% by volume. Similarly, a developed (patterned) photoresist layer can optionally be stripped using a stripping solution including at least 50% by volume of a fluorinated solvent, preferably at least 90% by volume. The term “% by volume” generally refers to the volume of an individual solvent measured prior to mixing relative to the total volume of a final solution or mixture. In the case of a photopolymer coating solution, however, the term “% by volume” refers to the volume of an individual solvent relative to the total volume of all other solvents and does not include the volume of the photopolymer. Depending on the particular material set and solvation needs of the process, the fluorinated solvent may be selected from a broad range of materials such as chlorofluorocarbons (CFCs), hydrochlorofluorocarbons (HCFCs), hydrofluorocarbons (HFCs), perfluorocarbons (PFCs), hydrofluoroethers (HFEs), perfluoroethers, perfluoroamines, trifluoromethyl-substituted aromatic solvents, fluoroketones and the like.

Particularly useful fluorinated solvents include those that are perfluorinated or highly fluorinated liquids at room temperature, which are immiscible with water and most (but not necessarily all) organic solvents. Among those solvents, hydrofluoroethers (HFEs) are well known to be highly environmentally friendly, “green” solvents. HFEs, including segregated HFEs, are preferred solvents because they are non-flammable, have zero ozone-depletion potential, lower global warming potential than PFCs, and show very low toxicity to humans.

Examples of readily available HFEs and isomeric mixtures of HFEs include, but are not limited to, an isomeric mixture of methyl nonafluorobutyl ether and methyl nonafluoroisobutyl ether (HFE-7100), an isomeric mixture of ethyl nonafluorobutyl ether and ethyl nonafluoroisobutyl ether (HFE-7200 aka Novec™7200), 3-ethoxy-1,1,1,2,3,4,4,5,5,6,6,6-dodecafluoro-2-trifluoromethyl-hexane (HFE-7500 aka Novec™7500), 1,1,1,2,3,3-hexafluoro-4-(1,1,2,3,3,3,-hexafluoropropoxy)-pentane (HFE 7600 aka Novec™7600), 1-methoxyheptafluoropropane (HFE-7000), 1,1,1,2,2,3,4,5,5,5-decafluoro-3-methoxy-4-trifluoromethylpentane (HFE-7300 aka Novec™7300), 1,3-(1,1,2,2-tetrafluoroethoxy)benzene (HFE-978m), 1,2-(1,1,2,2-tetrafluoroethoxy)ethane (HFE-578E), 1,1,2,2-tetrafluoroethyl-1H,1H,5H-octafluoropentyl ether (HFE-6512), 1,1,2,2-tetrafluoroethyl-2,2,2-trifluoroethyl ether (HFE-347E), 1,1,2,2-tetrafluoroethyl-2,2,3,3-tetrafluoropropyl ether (HFE-458E), and 1,1,1,2,2,3,3,4,4,5,5,6,6-tridecafluorooctane-propyl ether (TE6O-C3).

The fluorinated photopolymer composition of the present disclosure includes a fluorinated solvent and a fluorinated photopolymer material. The fluorinated photopolymer comprises at least three distinct repeating units, including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight. The term “repeating unit” is used broadly herein and simply means that there is at least one unit, typically more than one unit, on a polymer chain. The term is not intended to convey that there is necessarily any particular order or structure with respect to the other repeating units unless specified otherwise. When a repeating unit represents a low mol % of the combined repeating units, there may be only one unit on a polymer chain.

The photopolymer may be produced, for example, by co-polymerizing suitable monomers containing the desired repeating units along with a polymerizable group. The polymerizable group may, for example, be polymerized by step-growth polymerization using appropriate functional groups or by a chain polymerization such as radical polymerization. Some non-limiting examples of useful radical polymerizable groups include acrylates (e.g. acrylate, methacrylate, cyanoacrylate and the like), acrylamides, vinylenes (e.g., styrenes), vinyl ethers and vinyl acetates. Alternatively, the photopolymer be produced by functionalizing preformed polymers to attach desired repeating units. Although many of the embodiments below refer to polymerizable monomers, analogous structures and ranges are contemplated and within the scope of the present disclosure wherein one or more of the repeating units are formed instead by attachment to an intermediate polymer.

In an embodiment, the fluorinated photopolymer material includes a copolymer formed at least from a first monomer having a fluorine-containing group, a second monomer having an acid-forming precursor group, and a third monomer having anthracene-based sensitizing dye. Additional monomers may optionally be incorporated into the copolymer. The term copolymer includes oligomers in addition to higher MW polymers. The copolymer has a total fluorine content in a range of 15 to 60% by weight. In an embodiment, the total fluorine content is 30 to 60%, preferably 35 to 55% by weight. The copolymer is suitably a random copolymer, but other copolymer types can be used, e.g., block copolymers, alternating copolymers, and periodic copolymers. The copolymer may be optionally blended with one or more other polymers, preferably other fluorine-containing polymers, provided that the total fluorine content of the blended polymers is in a range of 15 to 60% by weight, relative to the total weight of the blended polymers.

The first monomer is one capable of being copolymerized with the second and third monomers and has at least one fluorine-containing group. In an embodiment, at least 70% of the fluorine content of the copolymer (by weight) is derived from the first monomer. In another embodiment, at least 85% of the fluorine content of the copolymer (by weight) is derived from the first monomer. Although the other two monomers may include fluorine, and there can be performance advantages when they do, some fluorine-containing substituents can be expensive. In certain embodiments, therefore, it is useful from a cost standpoint to rely on the first monomer for the fluorine content, rather than also preparing fluorinated second and third monomers if their substituents have high cost. In an embodiment, the first monomer is provided in a range of 40 to 90% by weight relative to the copolymer, alternatively in a range of 50 to 90% by weight, and preferably in a range of 60 to 80% by weight.

The first monomer includes a polymerizable group and a fluorine-containing group. Some non-limiting examples of useful polymerizable groups include acrylates (e.g. acrylate, methacrylate, cyanoacrylate and the like), acrylamides, vinylenes (e.g., styrenes), vinyl ethers, vinyl acetates, and epoxides. The fluorine-containing group is preferably an alkyl or aryl group that may optionally be further substituted with chemical moieties other than fluorine, e.g., chlorine, a cyano group, or a substituted or unsubstituted alkyl, alkoxy, alkylthio, aryl, aryloxy, amino, alkanoate, benzoate, alkyl ester, aryl ester, alkanone or monovalent heterocyclic group, or any other substituent that a skilled worker would readily contemplate that would not adversely affect the performance of the fluorinated photoresist. Throughout this disclosure, unless otherwise specified, any use of the term alkyl includes straight-chain, branched and cyclo alkyls. Preferably, the first monomer does not contain protic or charged substituents, such as hydroxy, carboxylic acid, sulfonic acid or the like.

In a preferred embodiment, the first monomer has a structure according to formula (1):

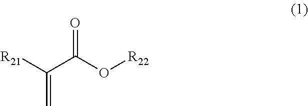

In formula (1), R₂₁ represents a hydrogen atom, a cyano group, a methyl group or an ethyl group. R₂₂ represents a substituted or unsubstituted alkyl group having at least 5 fluorine atoms, preferably at least 10 fluorine atoms. In an embodiment, the alkyl group is a hydrofluorocarbon or hydrofluoroether having at least as many fluorine atoms as carbon atoms. In a preferred embodiment R₂₂ represents a perfluorinated alkyl or a 1H,1H,2H,2H-perfluorinated alkyl having at least 4 carbon atoms. An example of the latter would be 1H,1H,2H,2H-perfluorooctyl (aka 2-perfluorohexyl ethyl), and a particularly useful first monomer includes 1H,1H,2H,2H-perfluorooctyl methacrylate (“FOMA”) and similar materials.

In an embodiment, the copolymer is formed from a fourth monomer in addition to the first, second and third monomers, wherein the fourth monomer is one capable of being copolymerized with the first, second and third monomers and has at least one fluorine-containing group. The fourth monomer may be selected from the same set of materials as described for the first monomer, but has a different chemical structure than the first monomer. In an embodiment, at least 70% of the fluorine content of the copolymer (by weight) is derived from the first and fourth monomers in combination. In another embodiment, at least 85% of the fluorine content of the copolymer (by weight) is derived from the first and fourth monomers in combination. In an embodiment, the first and fourth monomers are provided in a combined range of 50 to 90% by weight relative to the copolymer, and preferably in a range of 60 to 80% by weight.

The second monomer is one capable of being copolymerized with the first and third monomers. The second monomer includes a polymerizable group and either an acid-forming precursor group or an alcohol-forming precursor group. Some non-limiting examples of useful polymerizable groups include those described for the first monomer. Upon exposure to light, the acid- or alcohol-forming precursor group generates a polymer-bound acid, e.g., a carboxylic or sulfonic acid, or alcohol. This drastically changes its solubility relative to the unexposed regions thereby allowing development of an image with the appropriate solvent (typically fluorinated). In an embodiment, a carboxylic acid-forming precursor is provided in a range of 10 to 60% by weight relative to the copolymer, alternatively in a range of 10 to 30% by weight.

One class of acid-forming precursor groups includes the non-chemically amplified type. An example of a second monomer with such a group is 2-nitrobenzyl methacrylate. With this class, the acid-forming precursor groups are directly photo-labile to form a carboxylic acid group. The non-chemically amplified acid-forming precursor may be sensitized by the sensitizing dye on the third monomer to improve photo-efficiency or shift the spectral sensitivity.

A second class of acid-forming precursor groups includes the chemically amplified type. This typically requires a photo-acid generator (PAG) to be added to the photoresist composition, usually as a small molecule additive to the solution. The sensitizing dye on the third monomer absorbs light and forms an excited state capable of reacting with a PAG to generate a proton (an acid). The acid catalyzes the deprotection of acid groups of the acid-forming precursor, optionally with a post exposure bake step. Chemically amplified resists can be particularly desirable since they enable the exposing step to be performed through the application of relatively low energy light exposure (typically under 100 mJ/cm²). This is advantageous since many active organic materials useful in applications to which the present disclosure pertains may decompose in the presence of light, and therefore, reduction of the energy during this step permits the photoresist to be exposed without causing significant damage to underlying active organic layers. Also, decreased light exposure may be obtained by shorter exposure duration, improving the manufacturing throughput of the desired devices.

Examples of acid-forming precursor groups that yield a carboxylic acid include, but are not limited to: A) esters capable of forming, or rearranging to, a tertiary cation, e.g., t-butyl ester, t-amyl ester, 2-methyl-2-adamantyl ester, 1-ethylcyclopentyl ester and 1-ethylcyclohexyl ester; B) esters of lactone, e.g., γ-butyrolactone-3-yl, γ-butyrolactone-2-yl, mevalonic lactone, 3-methyl-γ-butyrolactone-3-yl, 3-tetrahydrofuranyl, and 3-oxocyclohexyl; C) acetal esters, e.g., 2-tetrahydropyranyl, 2-tetrahydrofuranyl, and 2,3-propylenecarbonate-1-yl; D) beta-cyclic ketone esters, E) alpha-cyclic ether esters and F) MEEMA (methoxy ethoxy ethyl methacrylate) and other esters which are easily hydrolyzable because of anchimeric assistance. In a preferred embodiment, the second monomer comprises an acrylate-based polymerizable group and a tertiary alkyl ester acid-forming precursor group, e.g., t-butyl methacrylate (TBMA) or 1-ethylcyclopentyl methacrylate (“ECPMA”).

The hydroxyl-forming precursor group (also referred to herein as an “alcohol-forming precursor group”) includes an acid-labile protecting group and the photopolymer composition typically includes a PAG compound and operates as a “chemically amplified” type of system. Upon exposure to light, the sensitizing dye excited state reacts in some way with the PAG to generate an acid, which in turn, catalyzes the deprotection of the hydroxyl-forming precursor group (optionally with a post exposure bake), thereby forming a polymer-bound alcohol (hydroxyl group). This significantly changes the solubility of the photopolymer relative to the unexposed regions thereby allowing development of an image with the appropriate fluorinated solvent. In an embodiment, the developing solution includes a fluorinated solvent that selectively dissolves unexposed areas.

In an embodiment, the hydroxyl-forming precursor has a structure according to formula (2):

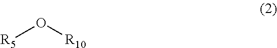

wherein R₅ is a carbon atom that forms part of the second repeating unit (or second polymerizable monomer), and R₁₀ is an acid-labile protecting group. Non-limiting examples of useful acid-labile protecting groups include those of formula (AL-1), acetal groups of the formula (AL-2), tertiary alkyl groups of the formula (AL-3) and silane groups of the formula (AL-4).

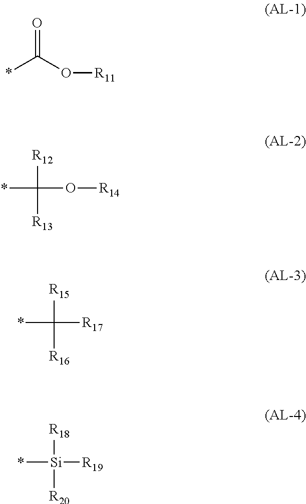

In formula (AL-1), R₁₁ is a monovalent hydrocarbon group, typically a straight, branched or cyclic alkyl group, of 1 to 20 carbon atoms that may optionally be substituted with groups that a skilled worker would readily contemplate would not adversely affect the performance of the precursor. In an embodiment, R₁₁ may be a tertiary alkyl group. Some representative examples of formula (AL-1) include:

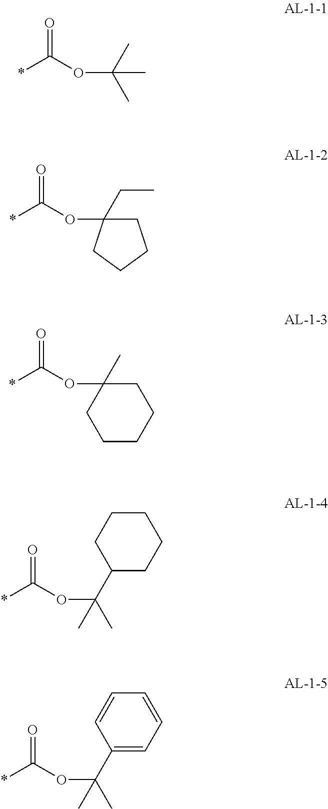

In formula (AL-2), R₁₄ is a monovalent hydrocarbon group, typically a straight, branched or cyclic alkyl group, of 1 to 20 carbon atoms that may optionally be substituted. R₁₂ and R₁₃ are independently selected hydrogen or a monovalent hydrocarbon group, typically a straight, branched or cyclic alkyl group, of 1 to 20 carbon atoms that may optionally be substituted. Some representative examples of formula (AL-2) include:

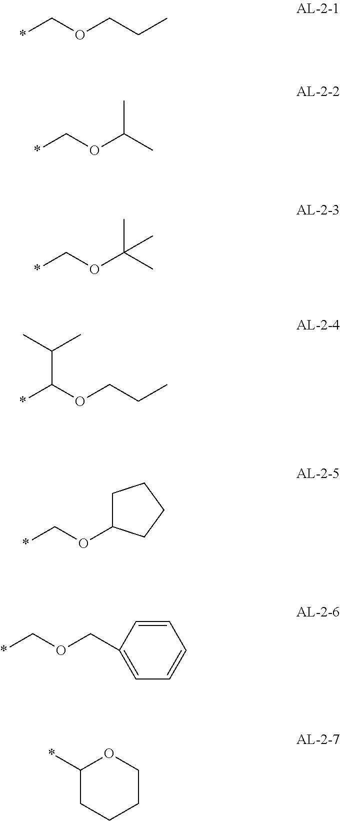

In formula (AL-3), R₁₅, R₁₆, and R₁₇ represent an independently selected monovalent hydrocarbon group, typically a straight, branched or cyclic alkyl group, of 1 to 20 carbon atoms that may optionally be substituted. Some representative examples of formula (AL-3) include:

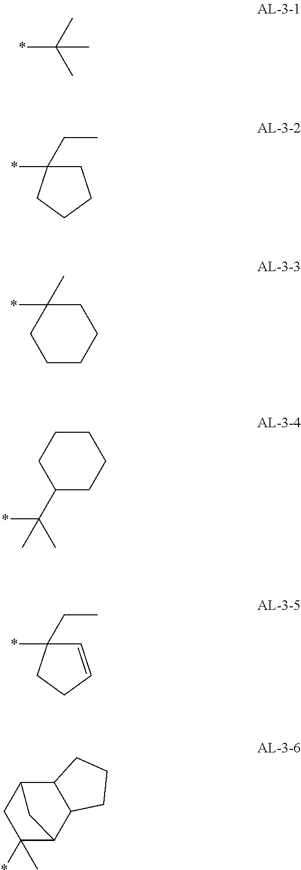

In formula (AL-4), R₁₈, R₁₉ and R₂₀ are independently selected hydrocarbon groups, typically a straight, branched or cyclic alkyl group, of 1 to 20 carbon atoms that may optionally be substituted.

The descriptions of the above acid-labile protecting groups for formulae (AL-2), (AL-3) and (AL-4) have been described in the context of hydroxyl-forming precursors. These same acid-labile protecting groups, when attached instead to a carboxylate group, may also be used to make some of the acid-forming precursor groups described earlier.

In a preferred embodiment, the developing solution includes a fluorinated solvent that selectively dissolves unexposed (“unswitched”) areas of the photopolymer.

Many useful PAG compounds exist that may be added to a photoresist composition. The PAG needs to have some solubility in the coating solvent. The amount of PAG required depends upon the particular system, but generally, will be in a range of 0.1 to 6% by weight relative to the photopolymer. In an embodiment, the presence of the anthracene-based sensitizing dye on the third monomer substantially reduces the amount of PAG required relative to a copolymer that does not incorporate the third monomer. In an embodiment, the amount of PAG is in a range of 0.1 to 2% relative to the copolymer. Fluorinated PAGs are generally preferred and non-ionic PAGs are particularly useful. Some useful examples of PAG compounds include 2-[2,2,3,3,4,4,5,5-octafluoro-1-(nonafluorobutylsulfonyloxyimino)-pentyl]-fluorene (ONPF) and 2-[2,2,3,3,4,4,4-heptafluoro-1-(nonafluorobutylsulfonyloxyimino)-butyl]-fluorene (HNBF). Other non-ionic PAGS include: norbornene-based non-ionic PAGs such as N-hydroxy-5-norbornene-2,3-dicarboximide perfluorooctanesulfonate, N-hydroxy-5-norbornene-2,3-dicarboximide perfluorobutanesulfonate, and N-hydroxy-5-norbornene-2,3-dicarboximide trifluoromethanesulfonate; and naphthalene-based non-ionic PAGs such as N-hydroxynaphthalimide perfluorooctanesulfonate, N-hydroxynaphthalimide perfluorobutanesulfonate and N-hydroxynaphthalimide trifluoromethanesulfonate.

Some additional classes of PAGs include: triarylsulfonium perfluoroalkanesulfonates, such as triphenylsulfonium perfluorooctanesulfonate, triphenylsulfonium perfluorobutanesulfonate and triphenylsulfonium trifluoromethanesulfonate; triarylsulfonium hexafluorophosphates (or hexafluoroantimonates), such as triphenylsulfonium hexafluorophosphate and triphenylsulfonium hexafluoroantimonate; triaryliodonium perfluoroalkanesulfonates, such as diphenyliodonium perfluorooctanesulfonate, diphenyliodonium perfluorobutanesulfonate, diphenyliodonium trifluoromethanesulfonate, di-(4-tert-butyl)phenyliodonium, perfluorooctanesulfonate, di-(4-tert-butyl)phenyliodonium perfluorobutanesulfonate, and di-(4-tert-butyl)phenyliodonium trifluoromethanesulfonate; and triaryliodonium hexafluorophosphates (or hexafluoroantimonates) such as diphenyliodonium hexafluorophosphate, diphenyliodonium hexafluoroantimonate, di-(4-tert-butyl)phenyliodonium hexafluorophosphate, and di-(4-tert-butyl)phenyliodonium hexafluoroantimonate. Suitable PAGs are not limited to those specifically mentioned above. Combinations of two or more PAGs may be used as well.

The third monomer is one capable of being copolymerized with the first and second monomers and includes an anthracene sensitizing dye. In an embodiment, the third monomer has a structure according to formula (3):

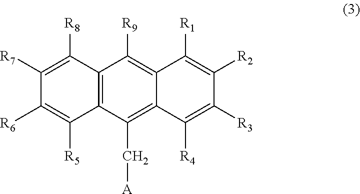

wherein A represents a moiety having a polymerizable group and R₁ through R₉ independently represent a hydrogen atom, a halogen atom, a cyano group, or a substituted or unsubstituted alkyl, alkoxy, alkylthio, aryl, aryloxy, amino, alkanoate, benzoate, alkyl ester, aryl ester, alkanone or monovalent heterocyclic group. Some non-limiting examples of polymerizable groups include those listed for the first monomer.

The anthracene-based sensitizing dye is selected to have a photoexcited state that is capable of reacting with a PAG to generate free acid in a chemically amplified system, or capable of reacting directly with the acid-forming precursor group of second monomer to form a polymer-bound acid. An advantage of the present embodiment is that, by incorporating the anthracene-based sensitizing dye into the fluorinated polymer, the dye no longer needs to be readily soluble in the coating or developing (or stripping) solvents. While a small molecule dye may have these issues, the fluorination level of the copolymer is such that it is still readily soluble to useful levels, even after incorporation of the dye. Nevertheless, in some embodiments, it is useful if the third monomer includes some amount fluorination. By doing so, the level of incorporation of sensitizing dye can be further increased thereby improving the photo-speed while maintaining a wide process window for developing and stripping steps. In addition, the presence of “free” small molecule sensitizing dye may adversely affect some active organic materials. By attaching the sensitizing dye, this risk is substantially reduced.

In an embodiment, the third monomer has no fluorine atoms and is provided in a range of 1 to 10% by weight relative to the copolymer. In another embodiment, the third monomer has no fluorine atoms and is provided in a range of 1 to 6% by weight relative to the copolymer. In a preferred aspect of this embodiment, the third monomer is provided in a range of 1 to 4% by weight relative to the copolymer.

In an embodiment, the third monomer includes one or more fluorine atoms (a fluorinated third monomer). The fluorine atoms can be included as part of the polymerizable group or as part of the sensitizing dye. Fluorine can be attached to an alkyl, aryl or heteroaryl moiety. In an embodiment, the third monomer has three or more fluorine atoms attached to an alkyl group. In an embodiment, a fluorinated third monomer is provided in a range of 1 to 20% by weight relative to the copolymer. In another aspect of this embodiment, the fluorinated third monomer is provided in a range of 5 to 15% by weight relative to the copolymer.

In an embodiment, the anthracene sensitizing dye has a light absorption peak in a range of 330 to 450 nm (as measured in a deposited film or in a fluorinated solvent solution). Although other wavelengths can be used, this range is compatible with many of the photolithographic, mercury lamp exposure units available in the industry that use i-line, h-line or g-line exposures. Many of the fluorinated photoresist systems of the prior art are designed for shorter wavelength radiation and have poor efficiency in this wavelength range. In an embodiment, the sensitizing dye enables sensitization of more than just i-line, h-line or g-line alone. For example, the sensitizing dye may have a light absorption peak in a range of 405 to 436 nm, and preferably, the light absorption at 405 nm is in a range of 0.33 to 3 times, preferably 0.5 to 2 times, the light absorption at 436 nm. Such a system has good sensitivity to both h-line and g-line radiation.

In an embodiment, polymerizable group A has a structure according to formula (4):

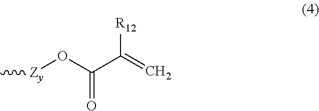

wherein R₁₂ represents a hydrogen atom, a cyano group or a substituted or unsubstituted alkyl group having 6 or fewer carbon atoms, Z represents a bridging group, and y=0 or 1. When y=1, Z can represent many possible bridging groups including, but not limited to, alkoxy, alkylthio, alkyl, arylalkyl, aryl, alkylaryl, aryloxy, amino, alkanoate, benzoate, alkyl ester, aryl ester, alkanone and heterocyclic groups, each of which may optionally be further substituted.

Some non-limiting examples of the third monomer include:

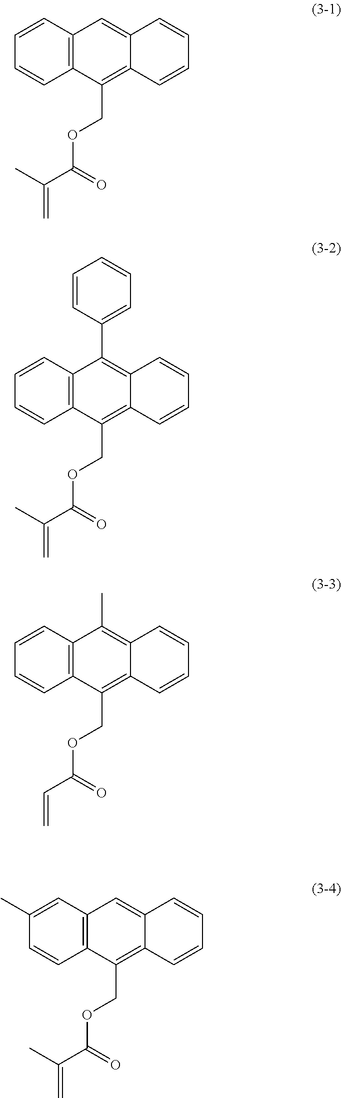 [SMILES: C=C(C)C(=O)OCc1c2ccccc2cc2ccccc12 ; C=C(C)C(=O)OCc1c2ccccc2c(-c2ccccc2)c2ccccc12 ; C=CC(=O)OCc1c2ccccc2c(C)c2ccccc12 ; C=C(C)C(=O)OCc1c2ccccc2cc2cc(C)ccc12]

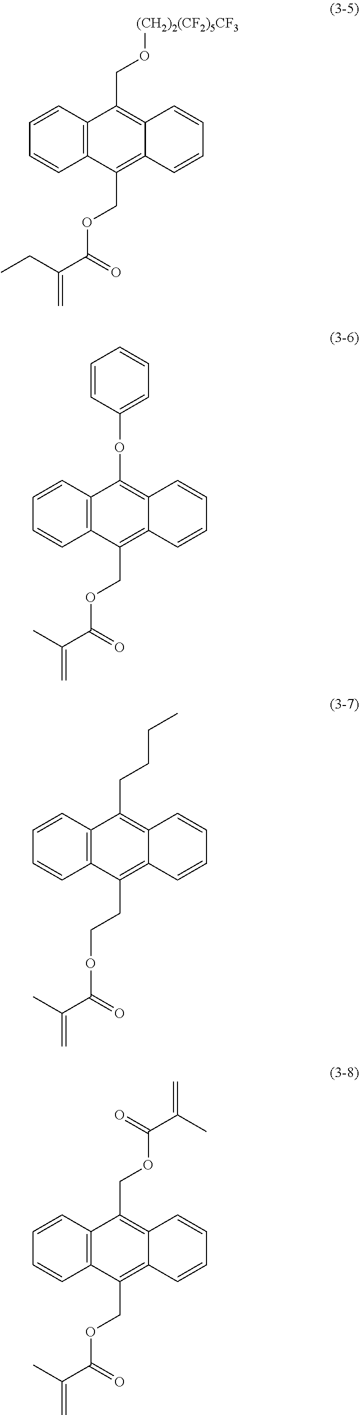

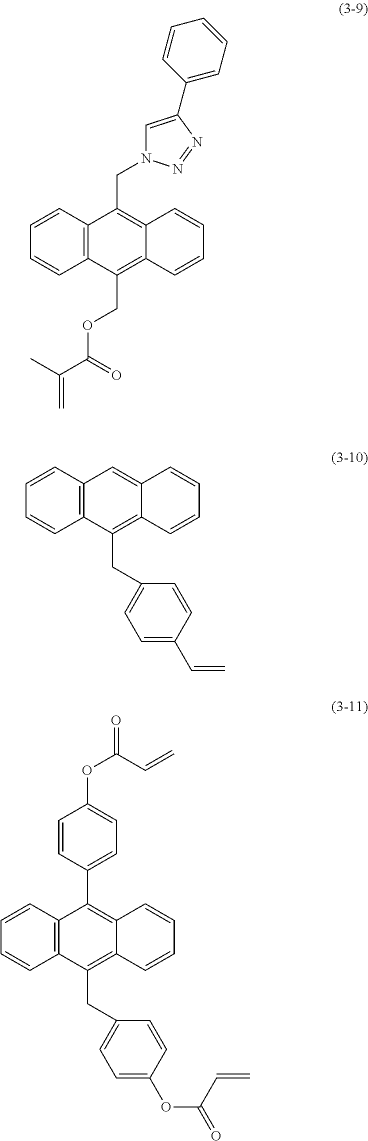

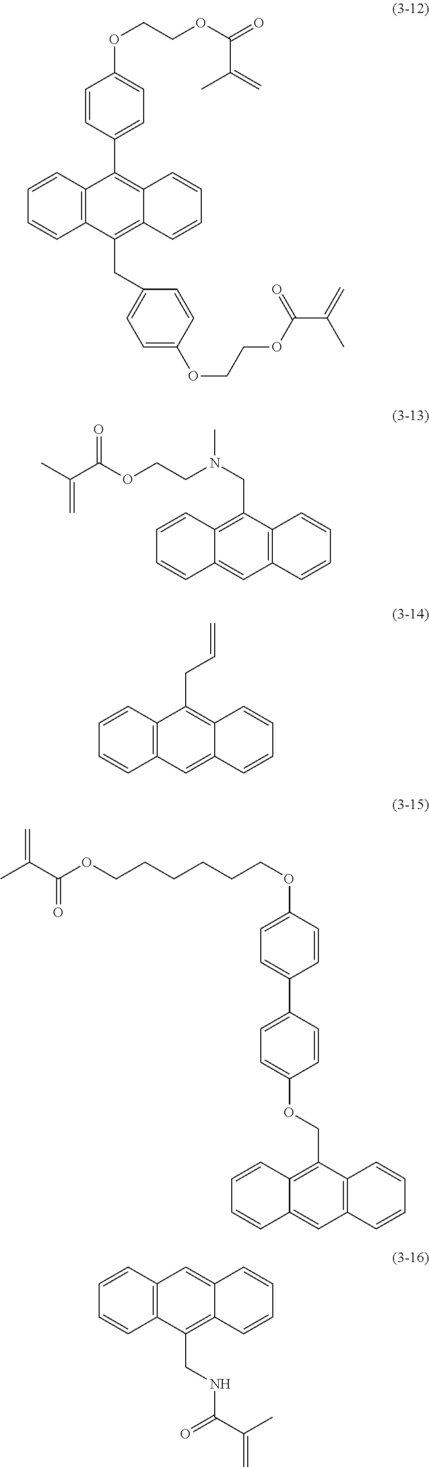

Preparation and polymerization of the monomers discussed above can generally be achieved using standard synthetic methods known to a skilled artisan. Some useful examples of the preparation of orthogonal photoresists can be found in US Publication No. 2011/0159252 and U.S. application Ser. No. 14/113,408, the entire contents of which are incorporated herein by reference. Examples of the preparation of polymers incorporating sensitizing dyes can be found in U.S. Pat. No. 8,338,529, U.S. Pat. No. 5,250,395, U.S. Pat. No. 7,632,630, U.S. Pat. No. 5,650,456, and U.S. Pat. No. 5,286,803, the entire contents of which are incorporated herein by reference.

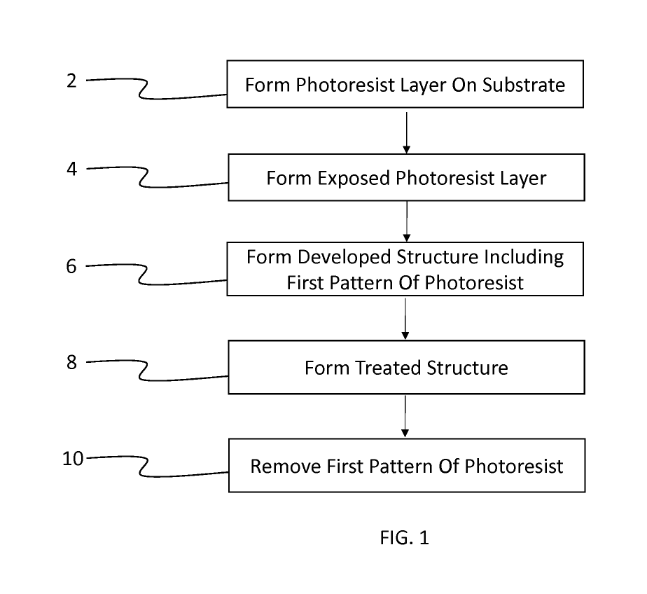

As previously mentioned, the composition of the present disclosure had many possible uses. A flow diagram for an embodiment of the present invention is shown in FIG. 1, and includes the step 2 of forming a photoresist layer (photopolymer layer) on a substrate. This can be accomplished, for example, by depositing a photopolymer composition of the present disclosure onto the substrate by spin coating, curtain coating, bead coating, bar coating, spray coating, dip coating or other methods capable of forming a film from a solution. The photoresist solution includes at least a fluorinated coating solvent and a fluorinated photopolymer material of the present disclosure dissolved or suspended in the coating solvent. Other additives may be present such as stabilizers, coating aids, acid scavengers (“quenchers”) and the like. Alternatively, the photoresist layer can be formed on the substrate by transferring a preformed photoresist layer (including a fluorinated photoresist material) from a carrier sheet, for example, by lamination transfer using heat, pressure or both. In such an embodiment, the substrate or the preformed photoresist layer may optionally have coated thereon an adhesion promoting layer.

In step 4, the photoresist layer is exposed to patterned radiation within the spectral sensitivity range of the sensitizing dye (e.g., light in a range of 330 nm to 450 nm), thereby forming an exposed photoresist layer. The patterned radiation forms areas of differential developability due to some chemical or physical change caused by the radiation exposure. Patterned radiation can be produced by many methods, for example, by directing exposing light through a photomask and onto the photoresist layer. Photomasks are widely used in photolithography and often include a patterned layer of chrome that blocks light. The photomask may be in direct contact or in proximity. When using a proximity exposure, it is preferred that the light has a high degree of collimation. Alternatively, the patterned light can be produced by a projection exposure device. In addition, the patterned light can be from a laser source that is selectively directed to certain portions of the photoresist layer.

In step 6, a developed structure is formed that includes a first pattern of photoresist. This can be done by contacting the exposed photoresist layer to a developing solution. The developing solution includes at least 50% by volume of a fluorinated solvent. During development, a portion of the exposed photoresist layer is removed in accordance with the patterned light. Depending on the nature of the chemical or physical change caused by the patterned light, the developing solution may dissolve the unexposed portion (negative working resist) or it may dissolve the exposed portion (positive working resist). In a preferred embodiment, the developing solution comprises a hydrofluoroether that dissolves the unexposed portion. In either case, it leaves behind a developed structure having a first pattern of photoresist that covers the substrate and a complementary second pattern of uncovered substrate corresponding to the removed portion of photoresist. By uncovered substrate, it is meant that the surface of the substrate is substantially exposed or revealed to a degree that it can be subjected to further treatments—a small amount of residual photopolymer may be present in some embodiments. Contacting the exposed photoresist layer can be accomplished by immersion into the developing solution or by coating it with the developing solution in some way, e.g., by spin coating or spray coating. The contacting can be performed multiple times if necessary. Although formation of the developed structure could be the last patterning step if the photoresist layer is intended to remain in the device, the developed structure may be subjected to further steps as described below.

In step 8, a treated structure is optionally formed by treating the developed structure in some way. In an embodiment, the treating includes a chemical or physical etch of the second pattern of uncovered substrate. In this case, the first pattern of photoresist acts as an etch barrier. In another embodiment, the treating includes chemically modifying the surface of the second pattern of uncovered substrate or the first pattern of photoresist. In another embodiment, the treating includes oxidation, reduction or doping of the second pattern of uncovered substrate, e.g., to modify its conductivity. In yet another embodiment, the treating includes coating the developed structure with, for example, an active organic material that is deposited both on the surface of the first pattern of photoresist and on the second pattern of uncovered substrate. In any of the above embodiments, the substrate may optionally include an active organic material layer such that the uncovered substrate is the surface of that active organic material layer.

In step 10, the first pattern of photoresist is optionally removed from the treated structure using a stripping solution. The stripping solution preferably includes at least 50% by volume of a fluorinated solvent. In embodiments wherein the surface of the first pattern of photoresist is covered with another layer of material, e.g., an active organic material layer, that portion is also removed. This is sometimes referred to as a “lift off” process.

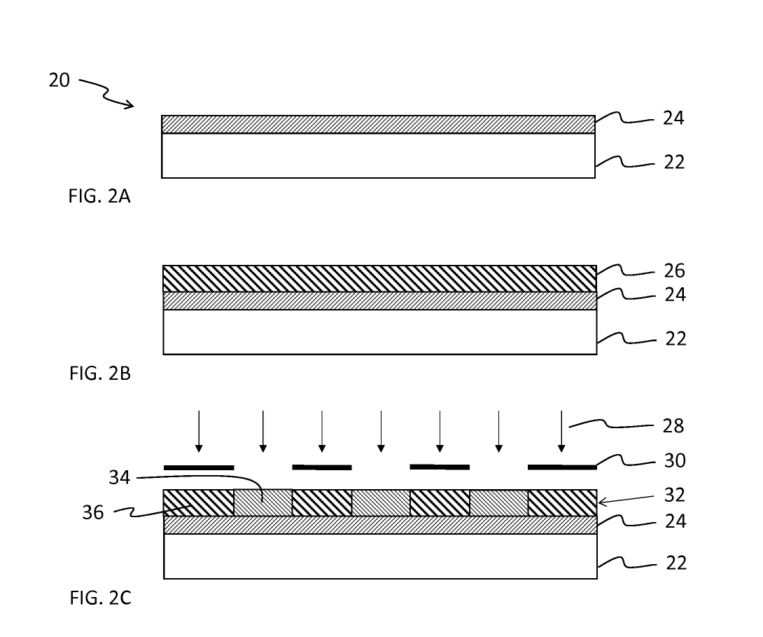

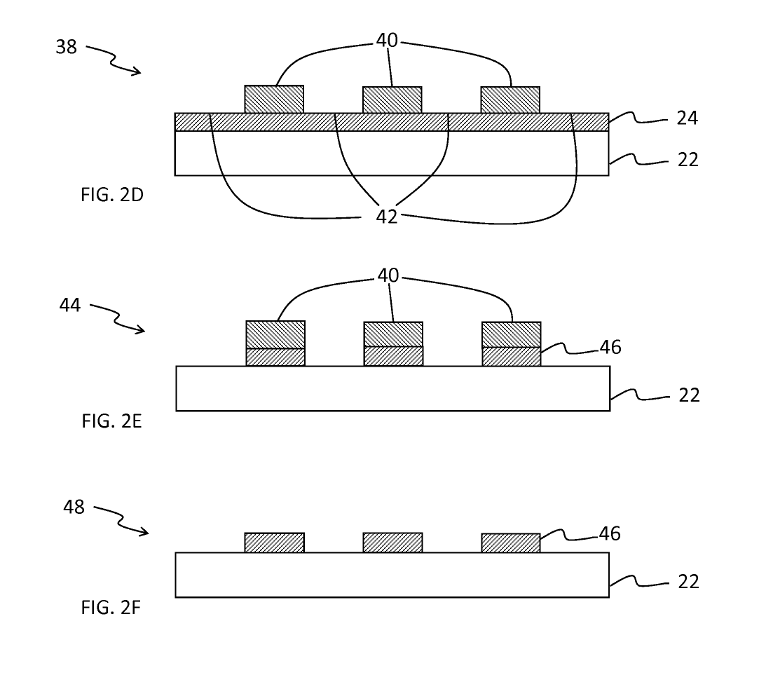

Turning now to FIG. 2, there is a series of cross-sectional views depicting the formation of a patterned active organic material structure at various stages according to an embodiment of the present invention. In FIG. 2A, a substrate 20 includes a layer of active organic material 24 provided on a support 22. In FIG. 2B, a negative-type photoresist layer 26 is formed on the substrate 20 and in contact with the layer of active organic material 24. Next, as shown in FIG. 2C, photoresist layer 26 is exposed to patterned light by providing a photomask 30 between the photoresist layer 26 and a source of collimated light 28. The exposed photoresist layer 32 includes exposed areas 34 and non-exposed areas 36. The structure is then developed in a developing solution including a fluorinated solvent. The non-exposed areas 36 of the photoresist are selectively dissolved to form a structure having a removed portion of photoresist. As shown in FIG. 2D, developed structure 38 has a first pattern of photoresist 40 covering the substrate, in this case the layer of active organic material 24, and a complementary second pattern of uncovered substrate 42, in this case the layer of active organic material 24, corresponding to the removed portion of photoresist. Turning now to FIG. 2E, a treated structure 44 is formed by subjecting the developed structure 38 to a chemical or physical etch that selectively removes active organic material from the second pattern of uncovered substrate, thereby forming a patterned layer of active organic material 46 corresponding to the first pattern. By corresponding, it is meant that the patterned layer of active organic material 46 substantially resembles that of the first pattern of photoresist 40, but the two patterns are not necessarily identical. For example, the etching might also etch the sidewalls of the patterned layer of active organic material, thereby making the dimensions slightly smaller than the first pattern. Conversely, etching kinetics or diffusion might be such that the dimensions of the patterned layer of active organic material are slightly larger than the first pattern. Further, the patterned layer of active organic material might not have vertical sidewalls as shown. Rather than rectangular, its cross section could resemble a trapezoid, an inverted trapezoid (undercut), or some other shape, e.g., one having curved sidewalls. Referring to FIG. 2F, treated structure 44 is contacted with a stripping solution that removes the first pattern of photoresist 40, thereby forming patterned active organic material structure 48 having the (now bare) patterned layer of active organic material 46. Patterned active organic material structure 48 may optionally be subjected to additional steps, if necessary, to form a functional device such as an organic TFT array, an OLED display, an e-reader, a solar cell, a bioelectronic device, a medical device and the like.

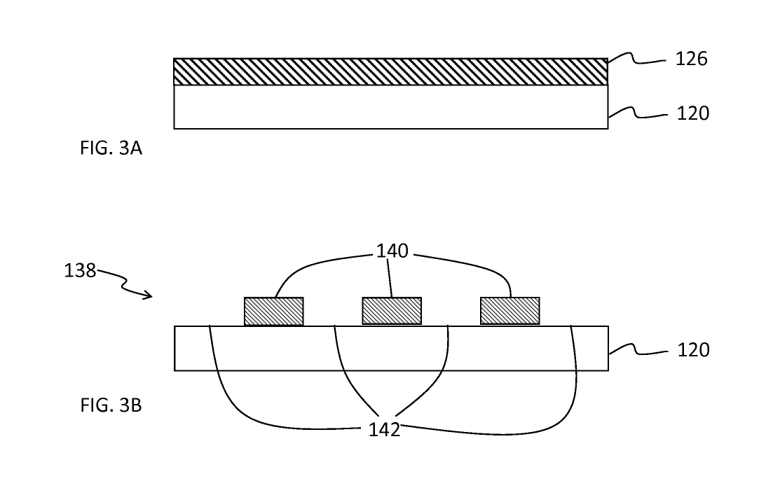

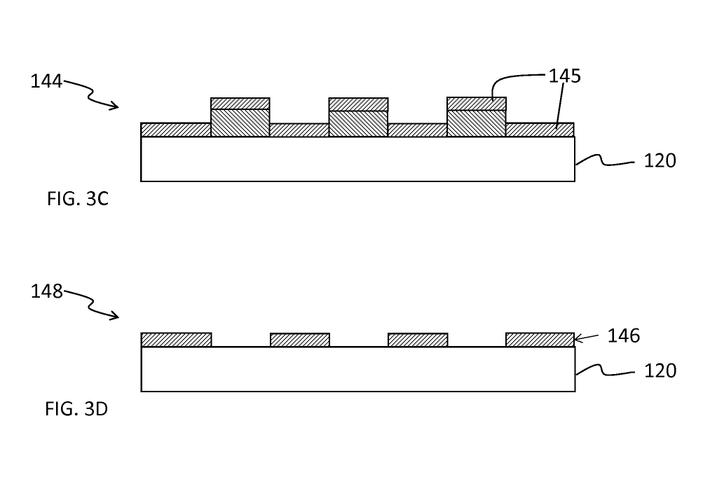

Turning now to FIG. 3, there is a series of cross-sectional views depicting the formation of a patterned active organic material structure at various stages according to another embodiment of the present invention. In FIG. 3A, a negative-type photoresist layer 126 is formed on substrate 120. This structure is then exposed and developed as described above to form developed structure 138, as shown in FIG. 3B. Developed structure 138 has a first pattern of photoresist 140 covering the substrate, and a complementary second pattern of uncovered substrate 142 corresponding to a removed portion of photoresist. Turning now to FIG. 3C, a treated structure 144 is formed by depositing a layer of active organic material 145 over both the first pattern of photoresist and the second pattern of uncovered substrate. In FIG. 3D, the treated structure 144 is then contacted with a stripping solution that removes the first pattern of photoresist and the active organic material deposited over the first pattern of photoresist, thereby forming patterned active organic material structure 148 having a patterned layer of active organic material 146 corresponding to the second pattern. By corresponding, it is meant that the patterned layer of active organic material 146 substantially resembles that of the second pattern of uncovered substrate 142, but the two patterns are not necessarily identical. Patterned active organic material structure 148 may optionally be subjected to additional steps, if necessary, to form a functional device such as an organic TFT array, an OLED display, an e-reader, a solar cell, a bioelectronic device, a medical device and the like.

In an embodiment, the developing solution and the stripping solution may each comprise a mixture of first and second fluorinated solvents, but at different ratios or concentrations. Preferably the fluorinated solvents are both hydrofluoroethers. In an embodiment, the first or second fluorinated solvent, or a mixture thereof, is also used as the coating solvent. The “mixed solvent” developing solution or the stripping solution may optionally be obtained at least in part from a recycled solvent mixture of the first and second solvents produced by a simple recycling apparatus acting on the photoresist waste stream as disclosed in co-pending U.S. 61/815,465, the teachings of which are incorporated by reference herein.

Some non-limiting embodiments of the present disclosure are described below:

### Embodiment 1

A composition comprising: a fluorinated solvent; and a fluorinated photopolymer comprising at least three distinct repeating units, including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight.

### Embodiment 2

The composition according to embodiment 1 wherein the photopolymer is a copolymer formed from a first monomer having a fluorine-containing group, a second monomer having an acid- or alcohol-forming precursor group, and a third monomer having a structure according to formula (3):

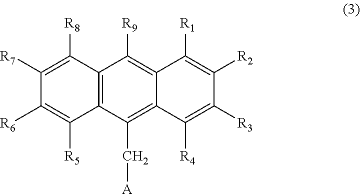

wherein A represents a moiety having a polymerizable group and R₁ through R₉ independently represent a hydrogen atom, a halogen atom, a cyano group, or a substituted or unsubstituted alkyl, alkoxy, alkylthio, aryl, aryloxy, amino, alkanoate, benzoate, alkyl ester, aryl ester, alkanone or monovalent heterocyclic group.

### Embodiment 3

The composition according to embodiment 2 wherein the structure comprises at least one fluorine atom.

### Embodiment 4

The composition according to any of embodiments 2-3 wherein R₉ is a substituted or unsubstituted aryl group.

### Embodiment 5

The composition according to embodiment 4 wherein the aryl group is selected from the group consisting of phenyl, biphenyl and naphthyl.

### Embodiment 6

The composition according to any of embodiments 2-5 wherein at least one of R₁ through R₉ (but other than R₉ in the case of embodiments 4 and 5) represents a fluorine-containing alkyl group or a fluorine-containing alkoxy group.

### Embodiment 7

The composition according to any of embodiments 2-5 wherein at least one of R₁ through R₉ (but other than R₉ in the case of embodiments 4 and 5) represents a perfluorinated alkoxy group, a 1H,1H,2H,2H-perfluorinated alkoxy, a perfluorinated alkyl or a 1H,1H,2H,2H-perfluorinated alkyl.

### Embodiment 8

The composition according to any of embodiments 2-7 wherein the polymerizable group includes an acrylate.

### Embodiment 9

The composition according to embodiment 8 wherein the acrylate has a structure according to formula (4):

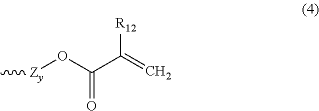

wherein R₁₂ represents a hydrogen atom, a cyano group or a substituted or unsubstituted alkyl group having 6 or fewer carbon atoms, Z represents a bridging group, and y=0 or 1.

### Embodiment 10

The composition according to embodiment 9 wherein y=1, Z is an alkyl or aryl having 1 to 6 carbon atoms and R₁₂ is hydrogen or methyl.

### Embodiment 11

The composition according to any of embodiments 2-7 wherein the polymerizable group includes a styrene or an acrylamide.

### Embodiment 12

The composition according to any of embodiments 2-11 wherein the second monomer is a carboxylic acid-forming precursor and is provided in a weight percentage range of 10 to 30% relative to the copolymer.

### Embodiment 13

The composition according to any of embodiments 1-12 wherein the sensitizing dye has a light absorption peak in a range of 330 to 450 nm.

### Embodiment 14

The composition according to any of embodiments 1-13 further comprising a non-ionic photo-acid generator compound.

### Embodiment 15

The composition according to any of embodiments 2-14 wherein the first monomer is provided in a range of 60 to 80% by weight relative to the copolymer.

### Embodiment 16

The composition according to any of embodiments 2-15 wherein the first monomer is a fluoroalkyl acrylate.

### Embodiment 17

The composition according to any of embodiments 2-16 wherein the third monomer has no fluorine atoms and wherein the third monomer is provided in a range of 1 to 4% by weight relative to the copolymer.

### Embodiment 18

The composition according to any of embodiments 2-17 wherein the third monomer has one or more fluorine atoms and wherein the third monomer is provided in a range of 1 to 20% by weight relative to the copolymer.

### Embodiment 19

Using the composition according to any of embodiments 1-18 to pattern one or more layers of a device.

### Embodiment 20

A method of patterning a device comprising: providing a layer of a fluorinated photopolymer over a device substrate, the fluorinated photopolymer comprising at least three distinct repeating units, including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight; exposing the photopolymer layer to patterned light to form an exposed photoresist layer; and contacting the exposed photopolymer layer with a developing agent to remove a portion of the exposed photopolymer layer in accordance with the patterned light, thereby forming a developed structure having a first pattern of photopolymer covering the substrate and a complementary second pattern of uncovered substrate corresponding to the removed portion of photopolymer, the developing agent comprising at least 50% by volume of a fluorinated solvent.

### Embodiment 21

The method according to embodiment 20 wherein the fluorinated solvent is a hydrofluoroether.

### Embodiment 22

The method according to any of embodiments 20-21 wherein the photopolymer has a total fluorine content in a range of 30 to 60% by weight.

### Embodiment 23

The method according to any of embodiments 20-22 wherein the device substrate comprises a support and a layer of active organic material, and wherein the photopolymer layer is in contact with the layer of active organic material.

### Embodiment 24

The method according to any of embodiments 20-23 further including: treating the developed structure to form a treated structure; and contacting the treated structure with a stripping agent to remove the first pattern of photopolymer.

### Embodiment 25

The method according to embodiment 24 wherein the treating includes providing a layer of active organic material (a second active organic material in the case where the device substrate includes a layer of active organic material) over both the first pattern of photopolymer and the second pattern of uncovered substrate, wherein the removal of the first pattern of photopolymer further removes active organic material formed over the first pattern of photopolymer, thereby forming a patterned layer of active organic material corresponding to the second pattern.

### Embodiment 26

The method according to any of embodiments 20-23 further including treating the developed structure to form a treated structure, wherein the treating includes chemical or physical etching of the active organic material in the second pattern of uncovered substrate, thereby forming a patterned layer of active organic material corresponding to the first pattern.

### Embodiment 27

The method according to any of embodiments 20-26 wherein the photopolymer is a copolymer formed from a first monomer having a fluorine-containing group, a second monomer having an acid- or alcohol-forming precursor group, and a third monomer having a structure according to formula (3):

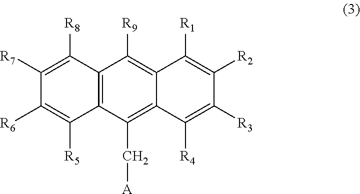

wherein A represents a moiety having a polymerizable group and R₁ through R₉ independently represent a hydrogen atom, a halogen atom, a cyano group, or a substituted or unsubstituted alkyl, alkoxy, alkylthio, aryl, aryloxy, amino, alkanoate, benzoate, alkyl ester, aryl ester, alkanone or monovalent heterocyclic group.

### Embodiment 28

The method according embodiment 27 wherein the total fluorine content of the copolymer is in a range of 35 to 55% by weight.

### Embodiment 29

The method according to any of embodiments 27-28 wherein the first monomer is provided in a range of 60 to 80% by weight relative to the copolymer.

### Embodiment 30

The method according to any of embodiments 27-29 wherein the first monomer is a fluoroalkyl acrylate.

### Embodiment 31

The method according to any of embodiments 27-30 wherein the third monomer has no fluorine atoms and wherein the third monomer is provided in a range of 1 to 4% by weight relative to the copolymer.

### Embodiment 32

The method according to any of embodiments 27-30 wherein the third monomer has one or more fluorine atoms and wherein the third monomer is provided in a range of 1 to 20% by weight relative to the copolymer.

### Embodiment 33

The method according to any of embodiments 27-32 wherein the second monomer is a carboxylic acid-forming precursor and is provided in a range of 10 to 30% by weight relative to the copolymer.

### Embodiment 34

The method according to any of embodiments 20-33 wherein the fluorinated solvent is selected from the group consisting of an isomeric mixture of methyl nonafluorobutyl ether and methyl nonafluoroisobutyl ether, an isomeric mixture of ethyl nonafluorobutyl ether and ethyl nonafluoroisobutyl ether, 3-ethoxy-1,1,1,2,3,4,4,5,5,6,6,6-dodecafluoro-2-trifluoromethyl-hexane, 1,1,1,2,3,3-hexafluoro-4-(1,1,2,3,3,3,-hexafluoropropoxy)-pentane, 1-methoxyheptafluoropropane, 1,1,1,2,2,3,4,5,5,5-decafluoro-3-methoxy-4-trifluoromethyl-pentane, 1,3-(1,1,2,2-tetrafluoroethoxy)benzene, 1,2-(1,1,2,2-tetrafluoroethoxy)ethane, 1,1,2,2-tetrafluoroethyl-1H,1H,5H-octafluoropentyl ether, 1,1,2,2-tetrafluoroethyl-2,2,2-trifluoroethyl ether, 1,1,2,2-tetrafluoroethyl-2,2,3,3-tetrafluoropropyl ether, and 1,1,1,2,2,3,3,4,4,5,5,6,6-tridecafluorooctane-propyl ether.

### EXAMPLES

### Synthesis Example 1

A copolymer solution was formed from the polymerization of: FOMA as a first monomer, TBMA as a second monomer and AMMA (Compound 3-1) as a third monomer. The relative ratios of the three monomers were 49.9/48.0/2.1 mol %, respectively, and the polymerization was carried out in a hydrofluoroether solvent. The total fluorine content of the copolymer was 42.5% by weight (relative to the total copolymer weight). Synthesis Example 1 further included 0.8 wt % PAG (relative to the copolymer weight), added to the solution. The following procedure was used.

A clean, dry 1 L four-neck jacketed reactor was equipped with a Teflon-blade mechanical stirrer, a reflux condenser having a mineral oil bubbler, a nitrogen inlet (the height of which could be adjusted to be below the surface of the reaction solution), and a programmable constant temperature bath (CTB) attached to the reactor jacket. To the reactor was charged FOMA (177.2 g, 0.410 mol), AMMA (4.7 g, 0.017 mol, from Osakashinyaku Co., Ltd) TBMA (56.0 g, 0.394 mol), AIBN (4.65 g, 0.028 mol) and Novec™7600 solvent (460.9 g). The nitrogen inlet was placed below the surface of the solution, and with good stirring, the reaction solution was sparged with nitrogen for 1 h. During the nitrogen sparge, the CTB was pre-warmed to 78° C. with the flow to the reactor jacket turned off. When the sparge was complete, the gas inlet tube was raised above the solution level and the nitrogen flow was reduced to maintain a slow flow through the system during the reaction. The valves between the pre-heated CTB and the reactor were opened and the reaction solution was stirred with heating for 18 h. The CTB was set to 21° C., and when the polymer solution was cooled, a total of 1283.7 g of Novec™7600 was added to the polymer solution to rinse it out of the reactor and to achieve a suitable viscosity for coating operations. A sample of the polymer solution could be removed at that point and either stripped of solvent or precipitated in cold methanol to provide a sample for analytical testing. Under yellow lights, PAG CGI 1907 (“ONPF”) from BASF (1.9032 g, 2.683 mmol) was added. The PAG slowly dissolves in the photoresist polymer solution over approximately 30 minutes. The light-sensitive solution was filtered repeatedly using nitrogen pressure through a 0.05 micrometer cartridge filter to provide a solution for coating.

### Synthesis Comparison 1

A copolymer solution was formed from the polymerization of: FOMA as a first monomer and TBMA as a second monomer. No third monomer was present. The relative ratios of the two monomers were 49.6/50.4 mol %, respectively, and the polymerization was carried out in a hydrofluoroether solvent. Synthesis Comparison 1 further included 3 wt % PAG (relative to the copolymer weight), added to the solution. The reaction conditions were similar to those as described in Synthesis Example 1. Synthesis Comparison 1 was prepared from FOMA (165.2 g, 0.382 mol), TBMA (55.1 g, 0.387 mol), AIBN (4.40 g, 0.0268 mol) and Novec 7600 solvent (437.5 g). When the reaction was complete, a total of 1178 g of Novec™7600 was added to the polymer solution to rinse it out of the reactor and achieve suitable viscosity. Under yellow lights PAG CGI 1907 (6.61 g, 9.32 mmol) was added. The resulting solution is filtered repeatedly using nitrogen pressure through a 0.05 micrometer cartridge filter to provide a solution for coating.

### Lithographic Examples

A series of fluorinated photoresist solutions were prepared based on Synthesis Comparison 1 and Synthesis Example 1. The series included various levels of AMMA incorporated into the copolymer in addition to various levels of PAG CGI 1907. The weight percentage of fluorine in the copolymer was always in a range of 36 to 43%. In this series, the mol % of AMMA is approximately equal to its weight percent. Each photoresist was tested as follows. A silicon wafer was primed by vapor depositing HMDS. A fluorinated photoresist solution was spin coated onto the silicon wafer and then “soft baked” at 90° C. for 60 seconds. The photoresist layer was about 1.0 to 1.5 μm thick. The photoresist was exposed through a reticle to patterned UV radiation (365 nm) with doses ranging from 40 mJ/cm2 to 880 mJ/cm2, followed by post-exposure baking at 70° C. for 120 sec. The exposed photoresist was then developed to remove the unexposed portion and to form a photoresist pattern on the substrate. Development times and developing solution compositions are shown in Table 1. Two applications of developer (approximately 10 mL each) were provided onto the photoresist layer to form a “puddle,” and the dwell time of each application was half of the total development time specified in Table 1. The wafer was spun dry at the end of each dwell time. After development, the samples were stripped by applying two (2) 60 sec puddles of Novec™7600 (total stripping time=120 sec).

TABLE 1

| | Developing agent | | |
|---|---|---|---|
| AMMA | Novec ™7300 | Novec ™7600 | Development Time |
| (mol %) | (% vol) | (% vol) | (sec) |
| 0 | 100 | 0 | 80 |
| 1 | 100 | 0 | 120 |
| 2 | 100 | 0 | 270 |
| 4 | 100 | 0 | 360 |
| 6 | 90 | 10 | 270 |
| 10 | 0 | 100 | 120 |

The samples were evaluated for photo-speed and stripping performance using Novec™7300 as the developing agent and Novec™7600 as the stripping agent. In this test, “good” photo-speed was observed when a developed pattern could be formed using less than 50 mJ/cm² exposure dose energy, “fair” photo-speed was observed when a developed pattern could be formed using an exposure dose energy in a range of 50 to 100 mJ/cm², and “poor” photo-speed was observed when a developed pattern could only be formed using an exposure dose energy greater than 100 mJ/cm² or when a developed pattern did not form at all for any exposure dose within the range. Stripping performance was evaluated based on the maximum exposure dose that a developed pattern received that could still be stripped, i.e., the pattern was “strippable”. In this test, “good” stripping performance was observed when the maximum exposure dose was greater than 400 mJ/cm², “fair” stripping performance was observed when the maximum exposure dose was in a range of 200 to 400 mJ/cm², and “poor” stripping performance was observed when the maximum exposure does was less than 200 mJ/cm². Table 2 shows the results wherein “speed” refers to photo-speed and “strip” refers to stripping performance. Note that not every material combination or property was evaluated, and so are left blank in Table 2.

TABLE 2

| | Comparison | | Example | | | | | | | | | |
|---|---|---|---|---|---|---|---|---|---|---|---|---|
| | AMMA (%) | | | | | | | | | | | |
| PAG | 0 | | 1 | | 2 | | 4 | | 6 | | 10 | |
| (%) | Speed | Strip | Speed | Strip | Speed | Strip | Speed | Strip | Speed | Strip | Speed | Strip |
| 0.1 | Poor | | Poor | Good | | | Fair | Good | | | | |
| 0.5 | Poor | | | | Fair | Good | | | Good | Poor | Good | Poor |
| 0.8 | Poor | | | | Good | Good | | | | | | |
| 1.0 | Poor | | Good | Fair | Good | Fair | Good | Fair | | | | |
| 3.0 | Good | Poor | Good | Poor | Good | Poor | Good | Poor | | | | |

As can be seen in Table 2, the comparison examples have very poor photo-speed except at high levels of PAG. When a high level of PAG is used, stripping can be difficult. When AMMA is incorporated, good or fair photo-speed can be achieved using much less PAG. There is a relatively wide range of useful AMMA/PAG combinations that are good or fair for both photo-speed and stripping performance. Although stripping becomes difficult above 4% AMMA in this experiment, the photo-speed is good with very low levels of PAG and the film could be used for applications where the fluorinated photoresist stays is not stripped. In embodiments where the photoresist is not stripped, the low level of PAG is advantaged because it is less likely to degrade potentially important film attributes or, if necessary, can more easily be washed out than the comparison at the highest PAG level. Although used in small amounts, the PAG can often be very expensive; thus, less PAG can also reduce manufacturing costs.

In another comparison example, a fluorinated photoresist composition was prepared based on Synthesis Comparison 1, with and without 9-anthracenemethanol added to the composition. Although this anthracene compound is analogous to AMMA, it had very low solubility and no significant improvement in photo-speed was observed.

The invention has been described in detail with particular reference to certain preferred embodiments thereof, but it will be understood that variations, combinations, and modifications can be effected by a person of ordinary skill in the art within the spirit and scope of the invention.

### LIST OF REFERENCE NUMBERS USED IN THE DRAWINGS

2 form photoresist layer on substrate step
4 form exposed photoresist layer step
6 form developed structure step
8 form treated structure step
10 remove first pattern of photoresist step
20 substrate
22 support
24 layer of active organic material
26 photoresist layer
28 light
30 photomask
32 exposed photoresist layer
34 exposed areas
36 non-exposed areas
38 developed structure
40 first pattern of photoresist
42 second pattern of uncovered substrate
44 treated structure
46 patterned layer of active organic material
48 patterned active organic material structure
120 substrate
126 photoresist layer
138 developed structure
140 first pattern of photoresist
142 second pattern of uncovered substrate
144 treated structure
145 layer of active organic material
146 patterned layer of active organic material
148 patterned active organic material structure

1. A method of patterning a device comprising:
providing on a device substrate a layer of a fluorinated photopolymer comprising at least three distinct repeating units including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight;
exposing the photopolymer layer to patterned light to form an exposed photopolymer layer; and
contacting the exposed photopolymer layer with a developing agent to remove a portion of the exposed photopolymer layer in accordance with the patterned light, thereby forming a developed structure having a first pattern of photopolymer covering the substrate and a complementary second pattern of uncovered substrate corresponding to the removed portion of photopolymer, the developing agent comprising at least 50% by volume of a fluorinated solvent.

2. The method of claim 1 wherein the fluorinated solvent is a hydrofluoroether or a mixture of hydrofluoroethers.

3. The method of claim 1 wherein the photopolymer has a total fluorine content in a range of 30 to 60% by weight.

4. The method of claim 1 wherein the device substrate comprises a support and a layer of active organic material, and wherein the photopolymer layer is in contact with the layer of active organic material.

5. The method of claim 1 further including:
treating the developed structure to form a treated structure; and
contacting the treated structure with a stripping agent to remove the first pattern of photopolymer.

6. The method of claim 5 wherein the substrate comprises a support and a layer of active organic material, and wherein the photopolymer layer is in contact with the layer of active organic material.

7. The method of claim 6 wherein the treating includes chemical or physical etching of the active organic material in the second pattern of uncovered substrate, thereby forming a patterned layer of active organic material corresponding to the first pattern.

8. The method of claim 5 wherein the treating includes providing a layer of active organic material over both the first pattern of photopolymer and the second pattern of uncovered substrate, wherein the removal of the first pattern of photopolymer further removes active organic material formed over the first pattern of photopolymer, thereby forming a patterned layer of active organic material corresponding to the second pattern.

9. The method of claim 1 wherein the photopolymer is a copolymer formed from a first monomer having a fluorine-containing group, a second monomer having an acid- or alcohol-forming precursor group, and a third monomer having a structure according to formula (3): 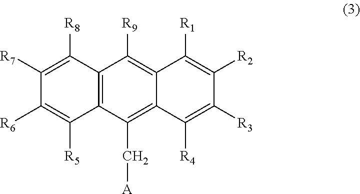
wherein A represents a moiety having a polymerizable group and R₁ through R₉ independently represent a hydrogen atom, a halogen atom, a cyano group, or a substituted or unsubstituted alkyl, alkoxy, alkylthio, aryl, aryloxy, amino, alkanoate, benzoate, alkyl ester, aryl ester, alkanone or monovalent heterocyclic group.

10. The method of claim 9 wherein the total fluorine content of the copolymer is in a range of 35 to 55% by weight.

11. The method of claim 9 wherein the first monomer is provided in a range of 40 to 90% by weight relative to the copolymer.

12. The method of claim 9 wherein the first monomer is a fluoroalkyl acrylate.

13. The method of claim 9 wherein the third monomer has no fluorine atoms and wherein the third monomer is provided in a range of 1 to 4% by weight relative to the copolymer.

14. The method of claim 9 wherein the third monomer has one or more fluorine atoms and wherein the third monomer is provided in a range of 1 to 20% by weight relative to the copolymer.

15. The method of claim 9 wherein the second monomer is a carboxylic acid-forming precursor and is provided in a range of 10 to 60% by weight relative to the copolymer.

16. A composition comprising:
a fluorinated solvent; and
a fluorinated photopolymer comprising at least three distinct repeating units, including a first repeating unit having a fluorine-containing group, a second repeating unit having an acid- or alcohol-forming precursor group, and a third repeating unit having an anthracene-based sensitizing dye, wherein the photopolymer has a total fluorine content in a range of 15 to 60% by weight.

17. The composition of claim 16 wherein the fluorinated solvent is a hydrofluoroether and the fluorinated photopolymer is formed from a first monomer having a fluorine-containing group, a second monomer having an acid- or alcohol-forming precursor group, and a third monomer having a structure according to formula (3): 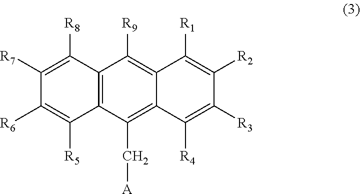
wherein A represents a moiety having a polymerizable group and R₁ through R₉ independently represent a hydrogen atom, a halogen atom, a cyano group, or a substituted or unsubstituted alkyl, alkoxy, alkylthio, aryl, aryloxy, amino, alkanoate, benzoate, alkyl ester, aryl ester, alkanone or monovalent heterocyclic group.

18. The composition of claim 17 wherein the structure comprises at least one fluorine atom.

19. The composition of claim 17 wherein R₉ is a substituted or unsubstituted aryl group selected from the group consisting of phenyl, biphenyl and naphthyl.

20. The composition of claim 17 wherein R₁ through R₉ represent a hydrogen atoms.
